(19) United States
(12) Patent Application Publication
(10) Pub. No.: US 2013/0062610 A1
(43) Pub. Date: Mar. 14, 2013

(54) LATTICE MATCHED CRYSTALLINE REFLECTOR

(71) Applicants: Andrew Clark, Los Altos, CA (US); Michael Lebby, Apache Junction, AZ (US); Robin Smith, Palo Alto, CA (US); David Williams, Menlo Park, CA (US)

(72) Inventors: Andrew Clark, Los Altos, CA (US); Michael Lebby, Apache Junction, AZ (US); Robin Smith, Palo Alto, CA (US); David Williams, Menlo Park, CA (US)

(21) Appl. No.: 13/232,069

(22) Filed: Sep. 14, 2011

(51) Int. Cl. H01L 33/32; H01L 33/60

(52) U.S. Cl. 257/76; 257/98; 438/29; 257/E33.072; 257/E33.025

(57) ABSTRACT

A virtual substrate structure with a lattice matched crystalline reflector for a light emitting device including a single crystal rare earth oxide layer deposited on a silicon substrate and substantially crystal lattice matched to the silicon substrate. A reflective layer of single crystal electrically conductive material is deposited on the layer of single crystal rare earth oxide and a layer of single crystal semiconductor material is positioned in overlying relationship to the reflective layer and substantially crystal lattice matched to the reflective layer. A single crystal rare earth oxide layer is optionally deposited between the reflective layer and the layer of semiconductor material.

### FIELD OF THE INVENTION

This invention relates in general to light emitting devices on silicon substrates and more specifically to crystalline reflectors in a substrate structure.

### BACKGROUND OF THE INVENTION

A semiconductor LED grown onto a substrate emits light in all directions. If an LED is grown onto a virtual substrate consisting of silicon and a transition layer, some of the light emitted from the LED impinges upon the substrate, a percentage of which is absorbed. Silicon typically absorbs 60% of the visible light hitting it, depending upon the wavelength above a band edge. It is therefore desirable to reflect the visible light from the LED before it reaches the silicon substrate, therefore making the LED more efficient because of improved light extraction.

Virtual substrates of the type discussed herein are lattice matched rare earth oxides that act as a transition layer to transition from a silicon substrate (wafer or portion thereof) on one side to the desired semiconductor (such as Ge, GaN, GaAs, etc.) on the other side. The key component of this design is to maintain single crystallinity from the substrate to the top semiconductor layer. These transition layers may be oxides, which are dielectrics and transmit visible light. See for example copending United States Patent Application entitled “IIIOₓN_{y} ON Single Crystal SOI Substrate and III N Growth Platform”, filed 30 Aug. 2011, bearing Ser. No. 13/221,474, and incorporated herein by reference.

One way to achieve this goal is to fabricate a Distributed Bragg Reflector (DBR) in the substrate structure, which is an alternating high-low-high-low refractive index stack tuned such that constructive interference occurs for a given wavelength in order to maximize reflection. See for example, the above described copending United States patent Application. Such an approach works well for light that is propagating normal to the plane of the wafer (and the DBR) but is less efficient at large angles from the surface normal.

It would be highly advantageous, therefore, to remedy the foregoing and other deficiencies inherent in the prior art.

Accordingly, it is an object of the present invention to provide a new and improved lattice matched crystalline reflector in a substrate structure.

It is another object of the present invention to provide a new and improved lattice matched crystalline reflector in a substrate structure that substantially improves LED efficiency.

It is another object of the present invention to provide new and improved methods of fabricating a lattice matched crystalline reflector in a substrate structure.

### SUMMARY OF THE INVENTION

Briefly, to achieve the desired objects and aspects of the instant invention in accordance with a preferred embodiment thereof, provided is a virtual substrate structure with a lattice matched crystalline reflector for a light emitting device. The structure includes a single crystal rare earth oxide layer deposited on a silicon substrate and substantially crystal lattice matched to the silicon substrate. A reflective layer of single crystal electrically conductive material is deposited on the layer of single crystal rare earth oxide and a layer of single crystal semiconductor material is positioned in overlying relationship to the reflective layer and substantially crystal lattice matched to the reflective layer. A single crystal rare earth oxide layer is optionally deposited between the reflective layer and the layer of semiconductor material.

The desired objects and aspects of the instant invention are further realized in accordance with a specific embodiment of a virtual substrate structure with a lattice matched crystalline reflector for a light emitting device. The structure includes a first at least one layer of single crystal Gadolinium oxide (Gd₂O₃) deposited on the silicon substrate. The first at least one layer of single crystal Gadolinium oxide (Gd₂O₃) is substantially crystal lattice matched to the silicon substrate. A reflective layer of single crystal electrically conductive ytterbium is deposited on the first at least one layer of single crystal Gadolinium oxide (Gd₂O₃) and a second at least one layer of single crystal Gadolinium oxide (Gd₂O₃) is deposited on the reflective layer. The second at least one layer of single crystal Gadolinium oxide (Gd₂O₃) is substantially crystal lattice matched to the reflective layer. A layer of either III oxide or III nitride single crystal semiconductor material is deposited on the second at least one layer of single crystal Gadolinium oxide (Gd₂O₃). The layer of III nitride single crystal semiconductor material is substantially crystal lattice matched to the reflective layer.

The desired objects and aspects of the instant invention are further realized in accordance with a method of fabricating a virtual substrate structure with a lattice matched crystalline reflector for a light emitting device including the step of depositing at least one layer of single crystal rare earth oxide on a silicon substrate. The layer of single crystal rare earth oxide is substantially crystal lattice matched to the silicon substrate. Depositing a reflective layer of single crystal electrically conductive material on the at least one layer of single crystal rare earth oxide, and positioning a layer of single crystal semiconductor material in overlying relationship to the reflective layer and substantially crystal lattice matched to the reflective layer.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram of a substrate structure for a light emitting device in accordance with the present invention;

FIG. 2 is a simplified layer diagram similar to FIG. 1 illustrating specific materials;

FIG. 3 is a simplified layer diagram similar to FIG. 2 illustrating a different embodiment;

FIG. 4 is a simplified layer diagram of another embodiment of a substrate structure for a light emitting device in accordance with the present invention;

FIG. 5 is a simplified layer diagram of another embodiment of a substrate structure for a light emitting device in accordance with the present invention; and

FIG. 6 illustrates the reflectivity of a very thin Ytterbium (Yb) film as compared to the reflectivity of a silicon wafer.

### DETAILED DESCRIPTION OF THE DRAWINGS

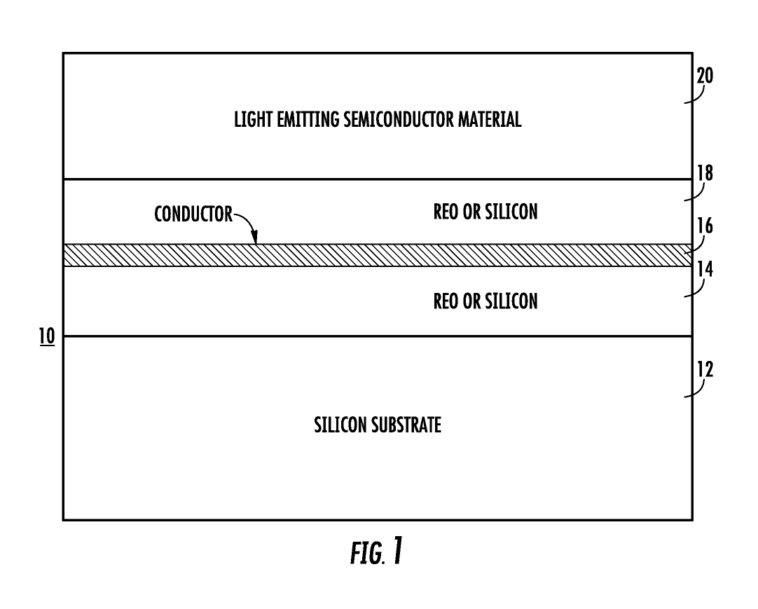

Referring to FIG. 1, a virtual substrate structure 10 with a lattice matched crystalline reflector for a light emitting device is illustrated. Structure 10 includes a single crystal silicon substrate 12 which may for example have a <111> upper face for the growth of additional layers. It should be understood however that the present invention is not limited to <111> silicon but that <110> and <100> silicon or variations thereof could also be used. Also, while silicon substrate 12 is illustrated as single crystal pure silicon it should be understood that single crystal substrates composed of materials containing elements other than silicon or in addition to silicon may be used.

A layer 14 of single crystal rare earth oxide (REO) or silicon is grown directly on the surface of silicon substrate 12. Throughout this disclosure whenever rare earth materials are mentioned it will be understood that “rare earth” materials are generally defined as any of the lanthanides as well as scandium and yttrium. In some applications it may be desirable to use a substrate composed of materials other than pure silicon and in these applications it will be understood that other rare earth materials that are substantially crystal lattice matched with the substrate material can be used if desired. Thus, layer 14 is relatively easily grown as a thin layer of single crystal material directly on substrate 12. The various layers of structure 10 can be grown by a variety of methods including MBE, MOCVD, PLD (pulsed laser deposition) sputtering, ALD (atomic layer epitaxy), or any other known growth method for thin films. Also, entire structure 10 or any part thereof can be grown in a single growth step in a method with less cost and easier to process or fabricate.

A single crystal electrically conductive layer 16 is deposited on layer 14 and a second layer 18 of single crystal rare earth oxide (REO) or silicon is grown directly on the surface of layer 16. Basically, layers 14, 16, and 18 form a single crystal mirror inside a rare earth oxide or silicon layer. It will be understood that in the application in which layer 18 is or includes single crystal silicon, the layer will be so thin that very little light absorption will occur. A layer 20 of light emitting single crystal semiconductor material, such as Ge, GaN, GaAs, etc., is deposited on the surface of layer 18 to serve as a virtual substrate for the later fabrication of electronic devices. Layers 14, 16, 18, and 20 are layers of single crystal material. Layers 14 and 18 may be graded from one mixture to another such that the REO layers can more precisely match the lattice constant of the material on both the top and bottom surfaces. Thus, a virtual substrate structure is provided that has the properties of a mirror as well as maintaining single crystallinity across the entire structure.

It will be understood that the mechanism of reflection from an electrical conductor's surface (e.g. conductor 16) is via interaction of the light's electric field with the mobile charge within the conductor. The electric field penetrates a characteristic skin-depth into the conductor, which is related to the frequency of light, the resistivity of the conductor, and the magnetic permeability of the conductor. Various candidate materials exist which are both conducting and may be deposited as single crystal films on either silicon or a single crystal rare earth oxide.

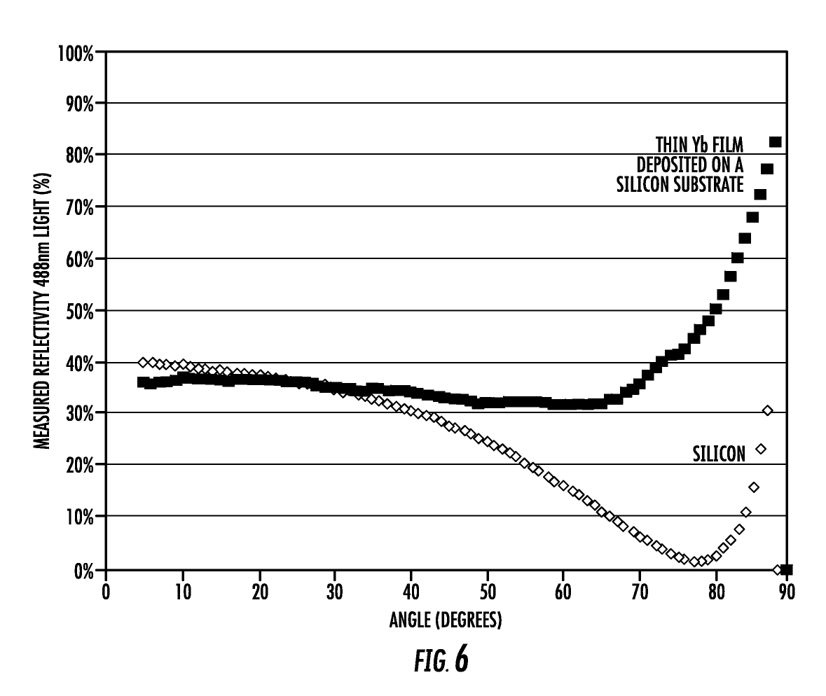

One possible implementation of conductor 16 is to use metals or semi-metals which are deposited as single crystal films. For example, referring to FIG. 6 the reflectivity of a very thin single crystal Ytterbium film on a silicon wafer illustrates the improvement in reflectivity at large angles from the surface normal. Ytterbium is a rare earth metal which is closely lattice matched to silicon, making it an ideal candidate for the mirror application of FIG. 1, since it may be deposited as a single crystal film either directly on silicon or on REO layer 14. Although ytterbium has a lattice constant that is very closely matched to silicon it has a high vapor pressure and so care must be taken when subsequent films are deposited on top of the ytterbium film. For this reason ytterbium metal may be alloyed with other rare earth elements, such as erbium or gadolinium, in order to increase the temperature stability of the films. It will of course be understood that entirely different rare earth metals may be used.

Zirconium Diboride is a semimetal that may be deposited as a single crystal on top of silicon, and may also be deposited on rare earth oxide films, for example, as layer 16 in FIG. 1.

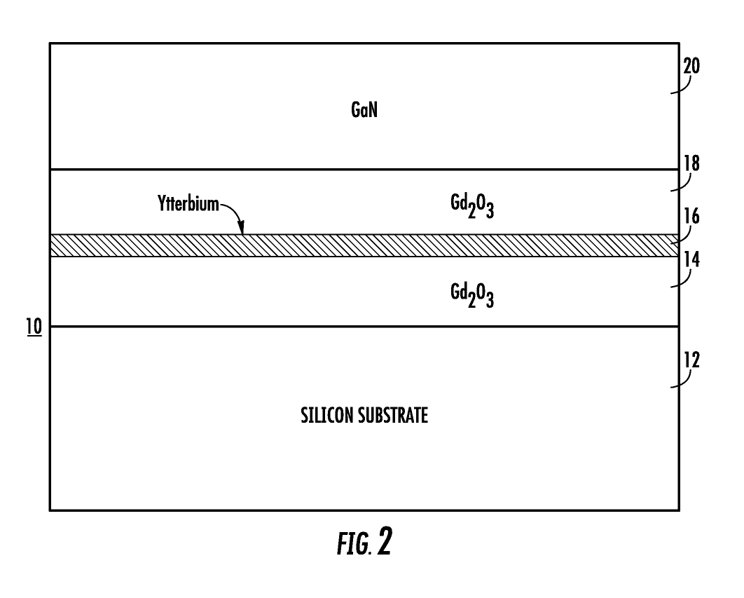

Referring additionally to FIG. 2, virtual substrate structure 10 with a lattice matched crystalline reflector for a light emitting device is illustrated with specific materials included to better illustrate the invention. In this specific example, substrate structure 10 includes a single crystal silicon substrate 12 which may for example have a <111> upper face for the growth of additional layers. Layer 14 includes a single crystal rare earth oxide, which in this specific example is gadolinium oxide (Gd₂O₃). Gadolinium oxide is good choice of material for lattice matching because silicon and gadolinium oxide are lattice matched in that the lattice parameter of Gd₂O₃ is approximately twice the lattice parameter of silicon.

In this specific example, electrically conductive layer 16 includes a thin film of ytterbium which, as stated above, is very closely matched to silicon so as to make it an ideal candidate. Layer 18 includes a single crystal rare earth oxide, which in this specific example is gadolinium oxide (Gd₂O₃). Gadolinium oxide layer 18 is an optional transition of dielectric material that electrically separates semiconductor layer 20 from electrically conductive layer 16 in applications where such a separation is either desired or required. Semiconductor layer 20, in this specific example is GaN but could be any other III nitride semiconductor material suitable for use as a virtual substrate where the III material is any metal selected from the III group in the periodic table. Also, gadolinium oxide layer 18 can be graded to more closely lattice match ytterbium layer 16 and GaN layer 20 or other III semiconductor material.

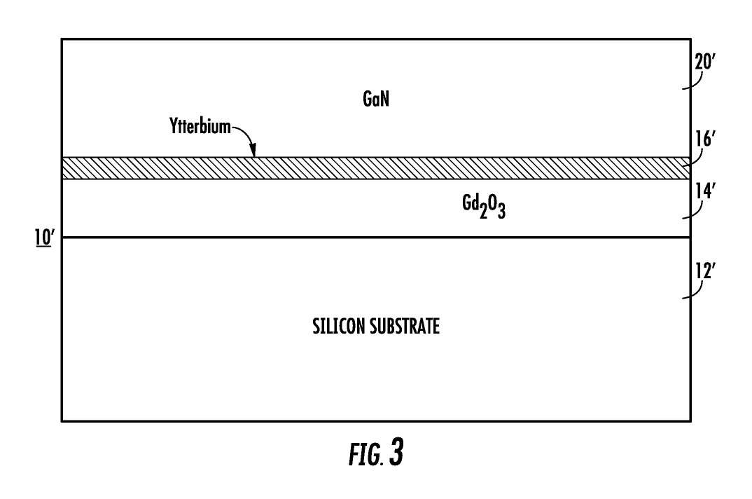

Turning now to FIG. 3, a different embodiment of a virtual substrate structure 10′ with a lattice matched crystalline reflector for a light emitting device, in accordance with the present invention, is illustrated. Substrate structure 10′ includes a silicon substrate 12′, a layer 14′ of single crystal rare earth oxide or silicon (in this example Gd₂O₃) deposited directly on the surface of silicon substrate 12′, an electrically conductive layer 16′ (in this example ytterbium) deposited directly on layer 14′, and a semiconductor layer 20′ deposited directly on electrically conductive layer 16′. In this specific example semiconductor layer 20′ is GaN but could be any other III nitride semiconductor material suitable for use as a virtual substrate. In this embodiment electrically conductive layer 16′ provides the functionality of being both a reflector and an electrode positioned on the bottom of virtual substrate 20′ which allows devices formed on virtual substrate 20′ to be driven electrically from one side of the device to the other.

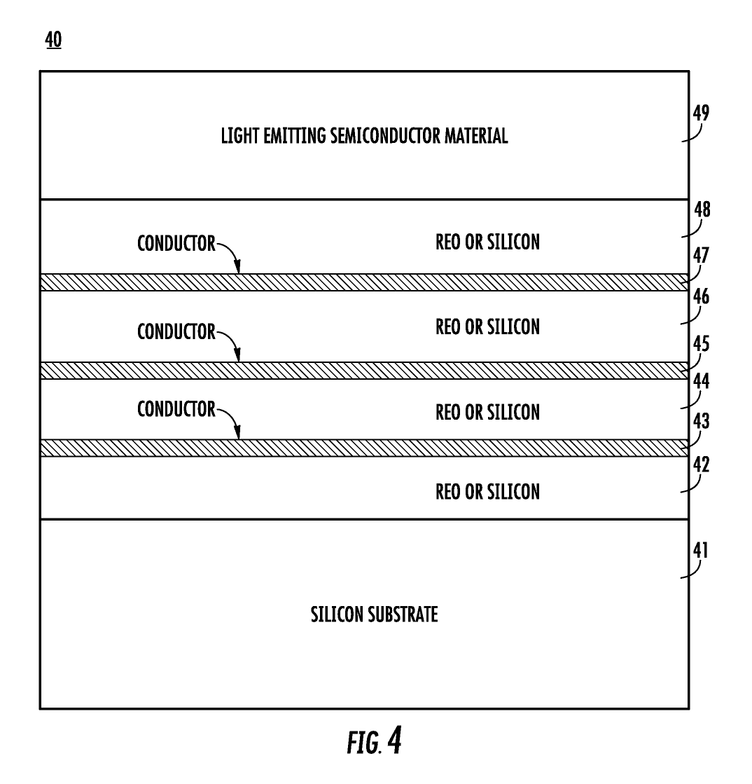

Turning now to FIG. 4, another embodiment of a virtual substrate structure 40 with a lattice matched crystalline reflector for a light emitting device in accordance with the present invention is illustrated. In this implementation a multilayer stack of several conductive films are interlaced between layers of rare earth oxide or silicon. Three layers of conductive films, designated 43, 45, and 47 are deposited between four layers of rare earth oxide or silicon, designated 42, 44, 46, and 48, with the entire multilayer stack deposited between a silicon substrate 41 and a virtual substrate 49 of light emitting conductive material. Also, more or fewer layers may be incorporated, as required by specific applications. All of the various films or layers can be formed of materials and using processes described above. A multilayer stack similar to that shown in FIG. 4 may be necessary if the specific conductor used cannot be grown thicker than a few skin-depths whilst maintaining good single crystal (crystalline) structure.

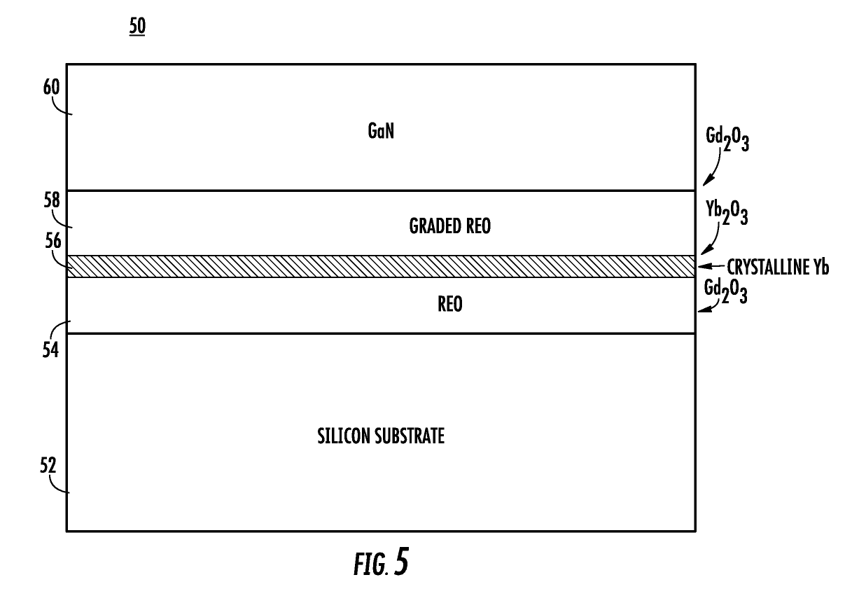

Turning now to FIG. 5, a specific example of a virtual substrate structure 50 with a lattice matched crystalline reflector for a light emitting device in accordance with the present invention is illustrated. In this specific example, substrate structure 50 includes a single crystal silicon substrate 52 which may for example have a <111> upper face for the growth of additional layers. Layer 54 includes a single crystal rare earth oxide, which in this specific example is gadolinium oxide (Gd₂O₃). Gadolinium oxide is good choice of material for lattice matching because silicon and gadolinium oxide are lattice matched in that the lattice parameter of Gd₂O₃ is approximately twice the lattice parameter of silicon. In this specific example, electrically conductive layer 56 includes a thin film of crystalline ytterbium oxide (Yb₂O₃) which is very closely matched to silicon so as to make it an ideal candidate. The Gd₂O₃ is present to prevent siliciding during the deposition steps. In some applications the crystalline Yb film may be deposited directly on silicon substrate 52 to eliminate one process step.

A single crystal REO layer 58 of graded REO, a rare earth oxide, in this specific example includes gadolinium oxide (Gd₂O₃) is deposited between electrically conductive layer 56 and a virtual substrate 60. Single crystal REO layer may be, for example, graded from crystalline ytterbium oxide (Yb₂O₃) adjacent layer 56 to Gadolinium oxide (Gd₂O₃) adjacent layer 60 to provide a closer lattice match. It should be noted that the grading can be incorporated in one of linearly or step wise. Other combinations of rare earth oxides might be used in layer 58, especially if a different reflector layer 56 is included and/or if a different III nitride material is included in layer 60.

Thus, in the present invention a new and improved virtual substrate structure with a lattice matched crystalline reflector for a light emitting device is disclosed. In all examples a virtual substrate structure is provided that has the properties of a mirror as well as maintaining single crystallinity across the entire structure. The new and improved lattice matched crystalline reflector in the substrate structure substantially improves LED efficiency. Also, new and improved methods of fabricating a virtual substrate structure with lattice matched crystalline reflector are disclosed.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A virtual substrate structure with a lattice matched crystalline reflector for a light emitting device comprising:
a crystalline silicon substrate;
at least one layer of single crystal rare earth oxide or silicon deposited on the silicon substrate and substantially crystal lattice matched to the silicon substrate;
a reflective layer of single crystal electrically conductive material deposited on the at least one layer of single crystal rare earth oxide or silicon; and
a layer of single crystal semiconductor material positioned in overlying relationship to the reflective layer and substantially crystal lattice matched to the reflective layer.

2. A virtual substrate structure with a lattice matched crystalline reflector for a light emitting device as claimed in claim 1 wherein the layer of single crystal semiconductor material is deposited directly on the reflective layer.

3. A virtual substrate structure with a lattice matched crystalline reflector for a light emitting device as claimed in claim 1 further including at least one layer of single crystal rare earth oxide or silicon positioned between the layer of single crystal semiconductor material and the reflective layer and substantially crystal lattice matched to both the layer of single crystal semiconductor material and the reflective layer.

4. A virtual substrate structure with a lattice matched crystalline reflector for a light emitting device as claimed in claim 3 wherein the at least one layer of single crystal rare earth oxide positioned between the layer of single crystal semiconductor material and the reflective layer is graded from crystalline ytterbium oxide (Yb₂O₃) adjacent the reflective layer to Gadolinium oxide (Gd₂O₃) adjacent the layer of semiconductor material.

5. A virtual substrate structure with a lattice matched crystalline reflector for a light emitting device as claimed in claim 4 wherein the at least one layer of single crystal rare earth oxide positioned between the reflective layer and the layer of single crystal semiconductor material is graded one of linearly or step wise.

6. A virtual substrate structure with a lattice matched crystalline reflector for a light emitting device as claimed in claim 3 wherein the at least one layer of single crystal rare earth oxide positioned between the layer of single crystal semiconductor material and the reflective layer includes Gadolinium oxide (Gd₂O₃).

7. A virtual substrate structure with a lattice matched crystalline reflector for a light emitting device as claimed in claim 1 wherein the at least one layer of single crystal rare earth oxide deposited on the silicon substrate includes Gadolinium oxide (Gd₂O₃).

8. A virtual substrate structure with a lattice matched crystalline reflector for a light emitting device as claimed in claim 1 wherein the reflective layer includes one of metals or semi-metals deposited as single crystal films.

9. A virtual substrate structure with a lattice matched crystalline reflector for a light emitting device as claimed in claim 7 wherein the reflective layer includes ytterbium.

10. A virtual substrate structure with a lattice matched crystalline reflector for a light emitting device as claimed in claim 1 wherein the layer of single crystal semiconductor material includes a III nitride.

11. A virtual substrate structure with a lattice matched crystalline reflector for a light emitting device as claimed in claim 10 wherein the layer of single crystal semiconductor material includes one of GaN, Ge, and GaAs.

12. A virtual substrate structure with a lattice matched crystalline reflector for a light emitting device as claimed in claim 1 wherein the reflective layer of single crystal electrically conductive material includes a multilayer stack of several conductive films interlaced between layers of rare earth oxide or silicon.

13. A virtual substrate structure with a lattice matched crystalline reflector for a light emitting device comprising:
a crystalline silicon substrate;
a first at least one layer of single crystal Gadolinium oxide (Gd₂O₃) deposited on the silicon substrate, the first at least one layer of single crystal Gadolinium oxide (Gd₂O₃) being substantially crystal lattice matched to the silicon substrate;
a reflective layer of single crystal electrically conductive ytterbium deposited on the first at least one layer of single crystal Gadolinium oxide (Gd₂O₃);
a second at least one layer of single crystal Gadolinium oxide (Gd₂O₃) deposited on the reflective layer, the second at least one layer of single crystal Gadolinium oxide (Gd₂O₃) being substantially crystal lattice matched to the reflective layer; and
a layer of III nitride single crystal semiconductor material deposited on the second at least one layer of single crystal Gadolinium oxide (Gd₂O₃), the layer of III nitride single crystal semiconductor material being substantially crystal lattice matched to the reflective layer.

14. A method of fabricating a virtual substrate structure with a lattice matched crystalline reflector for a light emitting device comprising the steps of:
providing a crystalline silicon substrate;
depositing at least one layer of single crystal rare earth oxide on the silicon substrate, the layer of single crystal rare earth oxide being substantially crystal lattice matched to the silicon substrate;
depositing a reflective layer of single crystal electrically conductive material on the at least one layer of single crystal rare earth oxide; and
positioning a layer of single crystal semiconductor material in overlying relationship to the reflective layer and substantially crystal lattice matched to the reflective layer.

15. A method as claimed in claim 14 wherein the steps of depositing at least one layer of single crystal rare earth oxide, depositing a reflective layer of single crystal electrically conductive material, and positioning a layer of single crystal semiconductor material are all performed using one of MBE, MOCVD, PLD (pulsed laser deposition) sputtering, and ALD (atomic layer epitaxy).

16. A method as claimed in claim 14 wherein the step of positioning the layer of single crystal semiconductor material includes depositing the layer of single crystal semiconductor material directly on the reflective layer.

17. A method as claimed in claim 14 wherein the step of positioning the layer of single crystal semiconductor material includes depositing at least one layer of single crystal rare earth oxide between the layer of single crystal semiconductor material and the reflective layer and substantially crystal lattice matched to both the layer of single crystal semiconductor material and the reflective layer.

18. A method as claimed in claim 14 wherein the step of positioning the layer of single crystal semiconductor material includes depositing a multilayer stack of several conductive films interlaced between layers of rare earth oxide or silicon on the reflective layer and depositing the layer of single crystal semiconductor material on the multilayer stack.

19. A method as claimed in claim 14 wherein the step of positioning the layer of single crystal semiconductor material includes depositing at least one layer of single crystal rare earth oxide between the layer of single crystal semiconductor material and the reflective layer and substantially crystal lattice matched to both the layer of single crystal semiconductor material and the reflective layer.

20. A method as claimed in claim 19 wherein the step of depositing at least one layer of single crystal rare earth oxide between the layer of single crystal semiconductor material and the reflective layer includes grading the at least one layer from crystalline ytterbium oxide (Yb₂O₃) adjacent the reflective layer to Gadolinium oxide (Gd₂O₃) adjacent the layer of semiconductor material.

21. A method as claimed in claim 19 wherein the at least one layer of single crystal rare earth oxide positioned between the reflective layer and the layer of single crystal semiconductor material is graded one of linearly or step wise.

22. A method of fabricating a virtual substrate structure with a lattice matched crystalline reflector for a light emitting device comprising the steps of:
providing a crystalline silicon substrate;
depositing a first at least one layer of single crystal Gadolinium oxide (Gd₂O₃) on the silicon substrate, the first at least one layer of single crystal Gadolinium oxide (Gd₂O₃) being substantially crystal lattice matched to the silicon substrate;
depositing a reflective layer of single crystal electrically conductive ytterbium on the first at least one layer of single crystal Gadolinium oxide (Gd₂O₃);
depositing a second at least one layer of single crystal Gadolinium oxide (Gd₂O₃) on the reflective layer, the second at least one layer of single crystal Gadolinium oxide (Gd₂O₃) being substantially crystal lattice matched to the reflective layer; and
depositing a layer of III nitride single crystal semiconductor material on the second at least one layer of single crystal Gadolinium oxide (Gd₂O₃) deposited on the reflective layer, the layer of III nitride single crystal semiconductor material being substantially crystal lattice matched to the reflective layer.
